(19) United States
(12) Patent Application Publication
(10) Pub. No.: US 2013/0298986 A1
(43) Pub. Date: Nov. 14, 2013

(54) METHOD FOR MANUFACTURING PHOTOELECTRIC CONVERSION ELEMENT AND PHOTOELECTRIC CONVERSION ELEMENT

(71) Applicant: FUJITSU LIMITED, Kawasaki-shi (JP)

(72) Inventor: Satoru Momose, Atsugi (JP)

(73) Assignee: FUJITSU LIMITED, Kawasaki (JP)

(21) Appl. No.: 13/946,126

(22) Filed: Jul. 19, 2013

Related U.S. Application Data
(63) Continuation of application No. PCT/JP2011/001759, filed on Mar. 25, 2011.

(51) Int. Cl. H01L 51/42

(52) U.S. Cl. CPC H01L 51/4253
USPC 136/256; 438/69

(57) ABSTRACT

A method for manufacturing a photoelectric conversion element includes: forming a hole injection layer by applying a solvent containing a first p-type organic semiconductor and an oxidant capable of oxidizing the first p-type organic semiconductor on a transparent substrate and a transparent electrode provided on the transparent substrate and by removing the solvent by drying to oxidize the first p-type organic semiconductor with the oxidant; forming a photoelectric conversion layer by applying a solvent containing an n-type organic semiconductor and a second p-type organic semiconductor on the hole injection layer and by removing the solvent by drying; and forming a metal electrode using a metal layer on the photoelectric conversion layer.

### CROSS-REFERENCE TO RELATED APPLICATION

This is a continuation of Application PCT/JP2011/001759, filed on Mar. 25, 2011, the entire contents of which are incorporated herein by reference.

### FIELD

The embodiments discussed herein are related to a method for manufacturing a photoelectric conversion element and a photoelectric conversion element.

### BACKGROUND

Attention has been paid to a technique in which a photoelectric conversion element including a so-called bulk heterojunction organic thin film as a photoelectric conversion layer is formed as an organic solar cell. In this technique, the photoelectric conversion element includes a transparent electrode, a hole injection layer provided on the transparent electrode, a bulk heterojunction photoelectric conversion layer provided on the hole injection layer, and a metal electrode composed of a metal, such as aluminum, provided on the photoelectric conversion layer.

The bulk heterojunction photoelectric conversion layer is an organic thin film formed in combination of a p-type organic semiconductor polymer and an n-type organic semiconductor such as a fullerene. In addition, the bulk heterojunction photoelectric conversion layer is formed by applying on an underlayer a mixed liquid containing a p-type organic semiconductor polymer and an n-type organic semiconductor, such as a fullerene, followed by drying.

In a step of drying the mixed liquid, the p-type organic semiconductor polymer and the n-type organic semiconductor, such as a fullerene, are spontaneously aggregated and phase-separated, and after the drying, small regions of the p-type organic semiconductor polymer and small regions of the n-type organic semiconductor are formed adjacent to each other. Accordingly, in the photoelectric conversion layer thus formed, a pn junction having a large specific area is formed (U.S. Pat. No. 5,331,183).

The hole injection layer is provide between the bulk heterojunction photoelectric conversion layer and the transparent electrode and enables electrons or holes to be easily given and received. As the hole injection layer, a polyethylenedioxythiophene (PEDOT), which is one type of polythiophene, doped with a poly(styrene sulfonic acid) (PSS), which is an acid having no oxidizing ability, has been used in general (C. J. Brabec, S. E. Sgaheen, T. Fromherz, F. Padinger, J. C. Hummelen, A. Dhanabalan, R. A. J. Janssen, N. S. Sariciftci: Synthetic Metals 121, 1517-1520 (2001)).

In the bulk heterojunction organic film solar cell as described above, when the aggregated n-type organic semiconductor fills gaps among the aggregated p-type organic semiconductor polymer in the photoelectric conversion layer, the aggregated n-type organic semiconductor and the hole injection layer come into contact with each other. As a result, holes in the hole injection layer and electrons generated in the n-type organic semiconductor are recombined with each other, so that a leak current is generated. Accordingly, when the light receiving quantity is decreased, and the number of carriers is decreased, the leak current is relatively increased, so that an open voltage Voc and a fill factor FF of the organic solar cell may be decreased in some cases.

In addition, carrier (hole or electron) conduction between the aggregated semiconductor polymer grains is carried out by carrier hopping performed at contact points between the aggregated identical semiconductor polymer grains. In the case described above, in the photoelectric conversion layer, although the specific surface area of the pn junction formed by the p-type organic semiconductor polymer and the n-type organic semiconductor is increased, the contact point area between the identical semiconductor polymer grains is decreased, so that the series resistance of the bulk heterojunction organic film solar cell is increased.

Hence, when the light receiving quantity is decreased, and the concentration of carriers to be generated is decreased, if the series resistance is high, a short-circuit current density and the fill factor may be decreased in some cases.

According to aspects of the invention, there are provided a method for manufacturing a photoelectric conversion element which has a high open voltage Voc or fill factor FF in a low light quantity region and which includes a photoelectric conversion layer composed of an organic thin film, and a photoelectric conversion element.

### SUMMARY

According to an aspect of the invention, A method for manufacturing a photoelectric conversion element includes: forming a hole injection layer by applying a solvent containing a first p-type organic semiconductor and an oxidant capable of oxidizing the first p-type organic semiconductor on a transparent substrate and a transparent electrode provided on the transparent substrate and by removing the solvent by drying to oxidize the first p-type organic semiconductor with the oxidant; forming a photoelectric conversion layer by applying a solvent containing an n-type organic semiconductor and a second p-type organic semiconductor on the hole injection layer and by removing the solvent by drying; and forming a metal electrode using a metal layer on the photoelectric conversion layer.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1A is a cross-sectional view of an element in a process for manufacturing a photoelectric conversion element of an embodiment;

FIG. 1B is a cross-sectional view of an element in the process for manufacturing a photoelectric conversion element of the embodiment;

FIG. 2A is a cross-sectional view of an element in the process for manufacturing a photoelectric conversion element of the embodiment;

FIG. 2B is a cross-sectional view of an element in the process for manufacturing a photoelectric conversion element of the embodiment;

FIG. 3A is a cross-sectional view of an element in the process for manufacturing a photoelectric conversion element of the embodiment;

FIG. 3B is a cross-sectional view of an element in the process for manufacturing a photoelectric conversion element of the embodiment;

FIG. 4 is a cross-sectional view of an element in the process for manufacturing a photoelectric conversion element of the embodiment;

FIG. 5 is a view of a chemical structure of a poly(3-hexylthiophene) (p3HT) and that of PCBM (phenyl-C61-butyric acid methyl ester);

FIG. 6 is a view of a thiophene polymer containing a polymer of thiophene as a main chain and an R group other than a hexyl group bonded to the 3-position of each thiophene unit, and a thiophene polymer containing a hexyloxy group as the R group;

FIG. 7 is a chemical structure of a PEDOT (polyethylenedioxythiophene) doped with a PSS (poly(styrene sulfonic acid));

FIG. 8A is an I-V graph of a photoelectric conversion element of Example 1 measured by light emitted from a fluorescent lamp;

FIG. 8B is an I-V graph of a photoelectric conversion element of Example 2 measured by light emitted from a fluorescent lamp;

FIG. 8C is an I-V graph of a photoelectric conversion element of Comparative Example measured by light emitted from a fluorescent lamp;

FIG. 9 is a table of features and electrical properties of the photoelectric conversion elements of Examples 1 and 2 and Comparative Example; and

FIG. 10 indicates a schematic cross-sectional view of the photoelectric conversion element of Example 1 and a cross-sectional STEM image of the photoelectric conversion element corresponding to the cross-sectional view.

### DESCRIPTION OF EMBODIMENTS

Hereinafter, embodiments will be described.

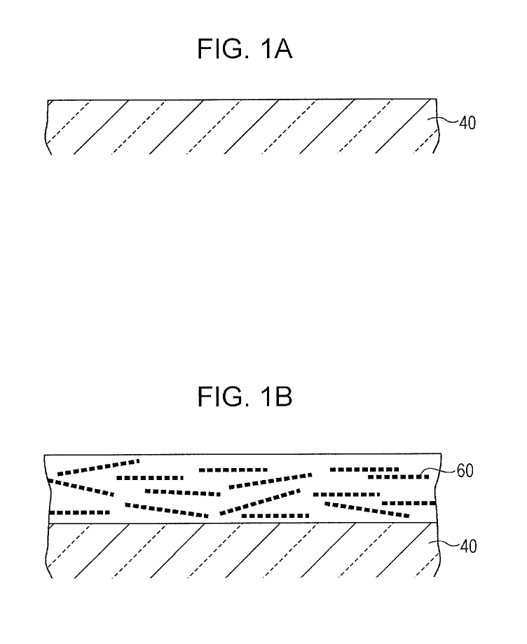

FIGS. 1A and 1B are each a cross-sectional view of an element in a process for manufacturing a photoelectric conversion element of this embodiment. FIG. 1A is a cross-sectional view of a transparent electrode (ITO 40) formed on a glass substrate of the photoelectric conversion element. The film thickness of the ITO 40 is approximately 200 nm. FIG. 1B is a cross-sectional view of the ITO 40 coated with an o-dichlorobenzene solution containing a poly(3-hexylthiophene) (P3HT) 60 by spin coating.

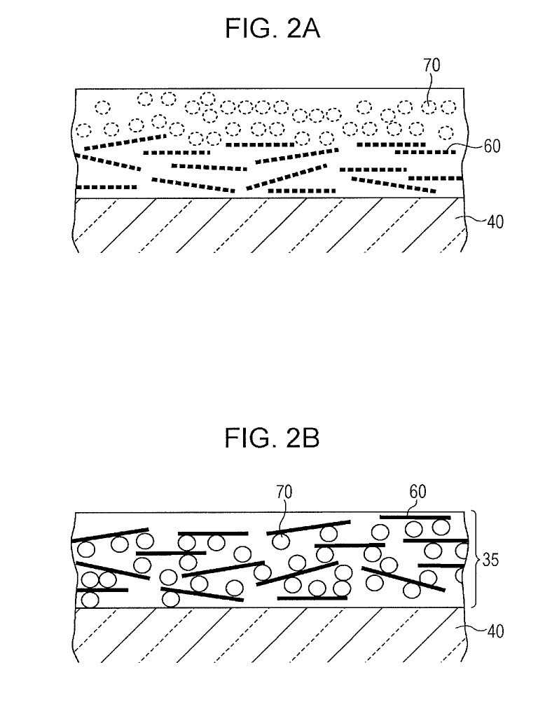

FIGS. 2A and 2B are each a cross-sectional view of an element in the process for manufacturing a photoelectric conversion element of this embodiment. FIG. 2A is a cross-sectional view of a thin film of the poly(3-hexylthiophene) (P3HT) 60 formed from the o-dichlorobenzene solution by spin coating, the thin film being coated with an isopropyl alcohol solution containing ferric chloride (FeCl₃) 70.

FIG. 2B is a cross-sectional view of an underlayer 35 having a thickness of approximately 5 nm obtained from the poly(3-hexylthiophene) (P3HT) 60 doped with the ferric chloride (FeCl₃) 70 by annealing a thin film containing the poly(3-hexylthiophene) (P3HT) 60 and the ferric chloride (FeCl₃) 70 at approximately 150° C. In the underlayer 35, aggregated poly(3-hexylthiophene) (P3HT) 60 molecules, each represented by a black bold line, are present, and between the molecules described above, molecules of the ferric chloride (FeCl₃) 70, each represented by a white circle, are present. In this case, the ferric chloride (FeCl₃) 70 functions as an oxidant to oxidize the poly(3-hexylthiophene) (P3HT) 60.

Incidentally, the underlayer 35 formed of the poly(3-hexylthiophene) (P3HT) 60 and the ferric chloride (FeCl₃) 70 has a low transparency as compared to that of an underlayer of a common photoelectric conversion element formed from a PEDOT (polyethylenedioxythiophene) and a PSS (poly(styrene sulfonic acid)). Hence, when the underlayer 35 formed of the poly(3-hexylthiophene) (P3HT) 60 and the ferric chloride (FeCl₃) 70 is used as a hole injection layer 30, the film thickness of the underlayer 35 is preferably approximately 10 nm or less so that incident light is not absorbed.

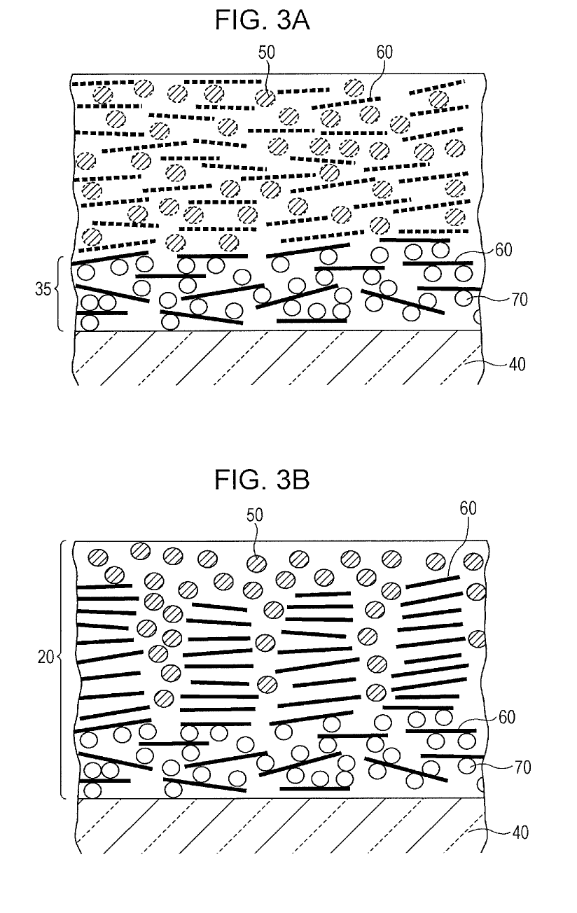

FIGS. 3A and 3B are each a cross-sectional view of an element in the process for manufacturing a photoelectric conversion element of this embodiment. FIG. 3A is a cross-sectional view of the underlayer 35 to which, after the surface thereof is washed with isopropyl alcohol and is then dried, an o-dichlorobenzene solution containing a poly(3-hexylthiophene) (P3HT) 60 and PCBM (phenyl-C61-butyric acid methyl ester) 50 is applied.

FIG. 3B is a cross-sectional view of a photoelectric conversion layer 20 obtained by drying a thin film formed from the o-dichlorobenzene solution containing a poly(3-hexylthiophene) (P3HT) 60 and PCBM (phenyl-C61-butyric acid methyl ester) 50. As o-dichlorobenzene is evaporated from the o-dichlorobenzene solution containing a poly(3-hexylthiophene) (P3HT) 60 and PCBM (phenyl-C61-butyric acid methyl ester) 50, by using the poly(3-hexylthiophene) (P3HT) 60 molecules present on the surface of the underlayer 35 as seeds, regions containing aggregated poly(3-hexylthiophene) (P3HT) 60 grains as a primary component grow in the photoelectric conversion layer 20 which is formed after the drying. By the function of the ferric chloride (FeCl₃) 70 used as an oxidant, the poly(3-hexylthiophene) (P3HT) 60 located at an underlayer 35 side is placed in a relatively electron deficient state. On the other hand, the poly(3-hexylthiophene) (P3HT) 60 in the o-dichlorobenzene solution containing a poly(3-hexylthiophene) (P3HT) 60 and PCBM 50, which collectively form the photoelectric conversion layer 20, is placed in a relatively electron-rich state because of inherent properties of a p-type semiconductor. Accordingly, since an interaction, that is, an attractive force, works between the poly(3-hexylthiophene) (P3HT) 60 in the underlayer 35 and the poly(3-hexylthiophene) (P3HT) 60 at a photoelectric conversion layer 20 side through overlap of their molecular orbitals, the poly(3-hexylthiophene) (P3HT) 60 at the photoelectric conversion layer 20 side is aggregated using the poly(3-hexylthiophene) (P3HT) 60 grains present on the surface of the underlayer 35 as base points. In addition, as the p-type organic semiconductor polymer contained in the photoelectric conversion layer 20, although the poly(3-hexylthiophene) (P3HT) 60 is used in the above case, a polythiophene derivative having the identical main chain to that of the poly(3-hexylthiophene) (P3HT) 60 and a side chain different from that thereof may also be used. The reason for this is that between the polythiophene derivative and the poly(3-hexylthiophene) (P3HT) 60 contained in the underlayer 35, an interaction, that is, an electron-sharing type attractive force, is generated through the overlap of their molecular orbitals as in the case described above. In addition, it has been known that when a thiophene polymer, which is a main chain of the poly(3-hexylthiophene) (P3HT) 60, is formed, in general, the ferric chloride (FeCl₃) 70 functions to advance a polymerization reaction between thiophene molecules by oxidation of a thiophene ring.

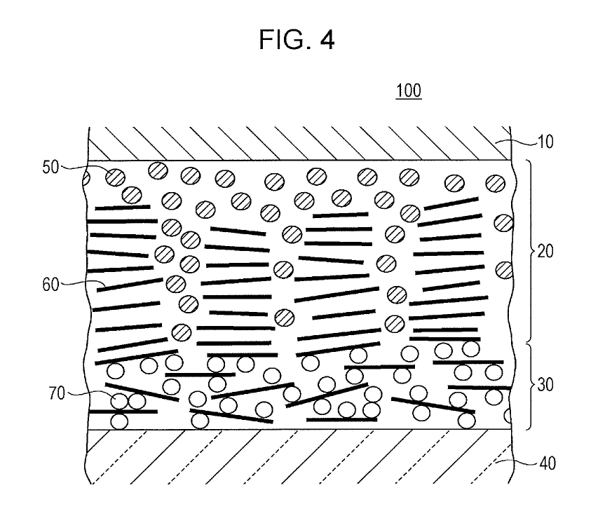

FIG. 4 is a cross-sectional view of an element in the process for manufacturing a photoelectric conversion element of this embodiment. FIG. 4 is a cross-sectional view indicating the state in which an aluminum upper electrode 10 having a thickness of approximately 150 nm is formed by a thermal deposition method on the photoelectric conversion layer 20, and an annealing treatment is performed at approximately 170° C. for approximately 5 minutes. In addition, since the underlayer 35 functions as the hole injection layer 30, in FIG. 4, the hole injection layer 30 is used instead of the underlayer 35. In addition, the hole injection layer 30 is a layer which is arranged between the bulk heterojunction photoelectric conversion layer and the transparent electrode and which enables electrons or holes to be easily given or received.

Accordingly, a photoelectric conversion element 100 is an organic thin film photoelectric conversion element including the ITO (transparent electrode) 40, the hole injection layer 30 provided on the ITO (transparent electrode) 40 and containing the oxidant and the p-type organic semiconductor polymer (poly(3-hexylthiophene) (P3HT) 60), and the photoelectric conversion layer 20 provided on the hole injection layer 30 and containing the n-type organic semiconductor and the p-type organic semiconductor polymer (poly(3-hexylthiophene) (P3HT) 60) at least having the identical main chain to that of the p-type organic semiconductor polymer (poly(3-hexylthiophene) (P3HT) 60) contained in the hole injection layer 30. In addition, the oxidant is an oxidant of capable of placing the p-type organic semiconductor polymer (poly(3-hexylthiophene) (P3HT) 60) in an electron deficient state by oxidation.

In addition, a method for manufacturing the organic thin film photoelectric conversion element described above includes forming a thin film using the o-dichlorobenzene solution containing a poly(3-hexylthiophene) (P3HT) 60 and PCBM 50 after the formation of the hole injection layer 30 containing the oxidant and the p-type organic semiconductor on the ITO (transparent electrode) 40.

Accordingly, as described with reference to FIGS. 3A and 3B, the poly(3-hexylthiophene) (P3HT) 60 at the photoelectric conversion layer 20 side is aggregated using the poly(3-hexylthiophene) (P3HT) 60 grains present on the surface of the hole injection layer 30 as base points.

Concomitant with the above aggregation, since the poly(3-hexylthiophene) (P3HT) 60 is also aggregated at the interface between the hole injection layer 30 and the photoelectric conversion layer 20, an area in which the n-type organic semiconductor in the photoelectric conversion layer 20 comes into contact with the p-type organic semiconductor in the hole injection layer 30 is decreased. As a result, a leak current generated by recombination between holes inside the hole injection layer 30 and electrons generated from the n-type organic semiconductor is decreased. Hence, even when the light receiving quantity is decreased, and the number of carriers is decreased, since the leak current in the organic solar cell is decreased, the open voltage Voc and the fill factor FF of the organic solar cell are improved.

Incidentally, as described with reference to FIGS. 2A and 2B, the transparency of the hole injection layer 30 containing the poly(3-hexylthiophene) (P3HT) 60 and the ferric chloride 70 is low as compared to that of a layer containing a PEDOT (polyethylenedioxythiophene) and a PSS (poly(styrene sulfonic acid)), which are contained in a common hole injection layer. Accordingly, when a layer formed of the poly(3-hexylthiophene) (P3HT) 60 and the ferric chloride 70 is used as the hole injection layer 30, the film thickness thereof is decreased (for example, to 5 nm) so as to suppress incident light from being absorbed by the hole injection layer 30 formed of the poly(3-hexylthiophene) (P3HT) 60 and the ferric chloride (FeCl₃) 70.

### EXAMPLES

### Example 1

A photoelectric conversion element 100 of Example 1 was formed by the following process. First, on a glass substrate provided with an ITO 40 having a film thickness of 200 nm as a transparent electrode, an o-dichlorobenzene solution containing a poly(3-hexylthiophene) 60 (P3HT, manufactured by ALDRICH Corp., average molecular weight: 87,000, regioregular type) at a concentration of 0.1 percent by weight was applied by spin coating. An isopropyl alcohol solution of ferric chloride at a concentration of 0.2 percent by weight was applied on an obtained thin film of the poly(3-hexylthiophene) (P3HT) 60, and an annealing treatment was then performed at 150° C., so that a hole injection layer 30 formed of a ferric chloride-doped poly(3-hexylthiophene) (P3HT) and having a thickness of 5 nm was obtained. After the surface of the hole injection layer 30 was washed with isopropyl alcohol and was then dried, an o-dichlorobenzene solution containing a poly(3-hexylthiophene) (P3HT) 60 and PCBM 50 at a weight ratio of 1:1, each concentration thereof being 1 percent by weight, was applied on the surface of the hole injection layer 30 by spin coating. After a solvent was removed by evaporation, an aluminum upper electrode film having a thickness of 150 nm was formed by deposition, and an annealing treatment was performed at 170° C. for 5 minutes. The film thickness of an obtained photoelectric conversion layer 20 containing the poly(3-hexylthiophene) (P3HT) 60 and the PCBM 50 was 100 nm.

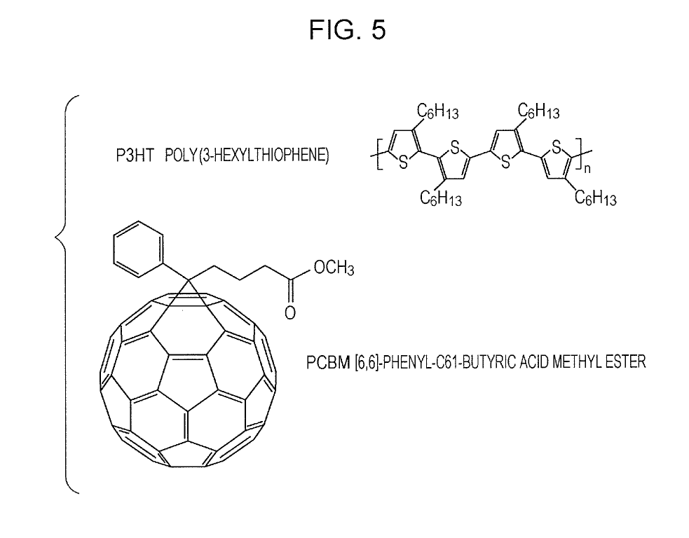

In addition, FIG. 5 indicates chemical formulas of the poly(3-hexylthiophene) (P3HT) 60 and the PCBM 50. The poly(3-hexylthiophene) (P3HT) 60 is a p-type organic semiconductor polymer containing a polymer of thiophene as a main chain and a hexyl group C₆H₁₃ (structural formula: CH₃CH₂CH₂CH₂CH₂CH₂) bonded to the 3-position of each thiophene unit. The PCBM 50 is an n-type organic semiconductor formed of a C60 fullerene and butyric acid methyl ester bonded thereto and is a substance dissolvable in an organic solvent.

### Example 2

A photoelectric conversion element 200 of Example 2 was a photoelectric conversion element as described below. First, the p-type semiconductor polymer used for the hole injection layer 30 in Example 1 was changed from the poly(3-hexylthiophene) (P3HT) 60 to a poly(3-hexyloxythiophene). A photoelectric conversion layer 20 having a thickness of 100 nm was formed using methods and conditions similar to those of Example 1 to contain a poly(3-hexylthiophene) (P3HT) 60 and PCBM 50 at a weight ratio of 1:1.

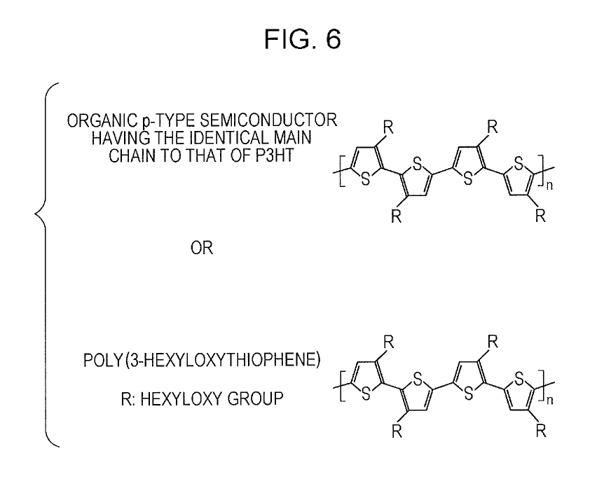

In addition, FIG. 6 indicates a thiophene polymer formed of a polymer of thiophene as a main chain and an R group other than a hexyl group bonded to the 3-position of each thiophene unit and a thiophene polymer in which as the above R group, a hexyloxy group is used. In addition, the poly(3-hexyloxythiophene) is a p-type organic semiconductor.

### Comparative Example

A photoelectric conversion element of Comparative Example was a photoelectric conversion element as described below. In the photoelectric conversion element of Comparative Example, as materials forming a hole injection layer, common materials, a PEDOT (polyethylenedioxythiophene) and a PSS (poly(styrene sulfonic acid)), were used. That is, the hole injection layer (film thickness: 40 nm) of Comparative Example contained a PEDOT (polyethylenedioxythiophene) and a PSS (poly(styrene sulfonic acid)) instead of the poly(3-hexylthiophene) (P3HT) 60 and the ferric chloride (FeCl₃) used in Example 1. In addition, a photoelectric conversion layer having a thickness of 100 nm was formed using methods and conditions similar to those of Example 1 to contain a poly(3-hexylthiophene) (P3HT) 60 and PCBM 50 at a weight ratio of 1:1.

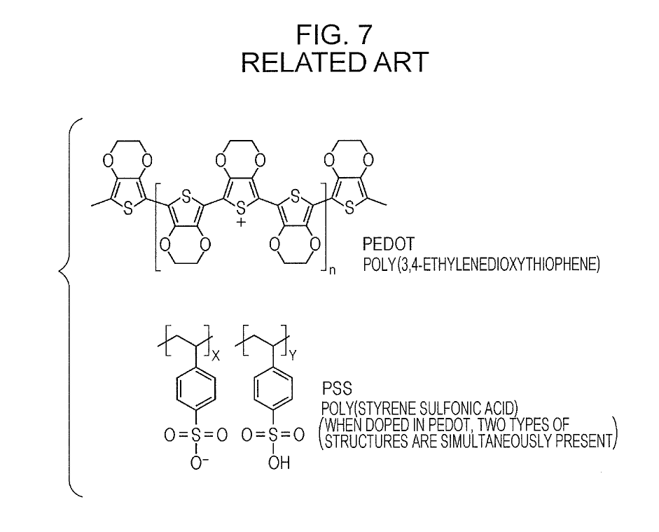

In addition, FIG. 7 indicates a PEDOT (polyethylenedioxythiophene) and a PSS (poly(styrene sulfonic acid)). When a PEDOT (polyethylenedioxythiophene) is doped with a PSS (poly(styrene sulfonic acid), an organic semiconductor having a p-type conductivity is obtained.

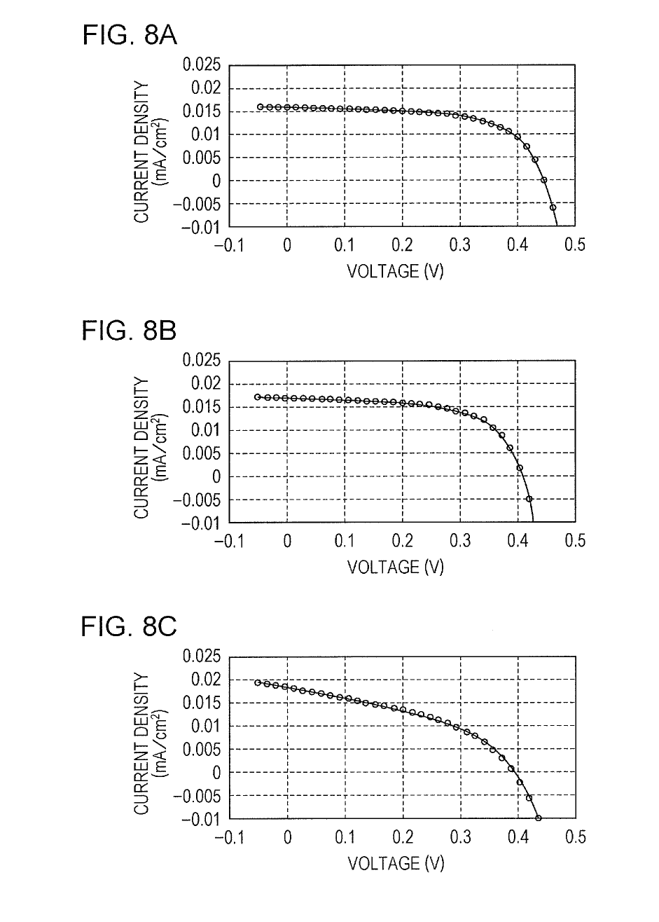

FIGS. 8A, 8B, and 8C indicate I-V graphs of the photoelectric conversion elements of Example 1, example 2, and Comparative Example, respectively, each of which was measured by light emitted from a fluorescent lamp. In each graph, the horizontal axis indicates a bias voltage (V), and the vertical axis indicates a current density (mA/cm²). In addition, each photoelectric conversion element was irradiated with light emitted from a fluorescent lamp (white light) having an irradiance of 89 μW/cm².

FIG. 8A is the I-V graph of the photoelectric conversion element 100 of Example 1. According to the graph in FIG. 8A, in the photoelectric conversion element 100 of Example 1, the open-circuit voltage Voc was 0.45 V, and the short-circuit current density Jsc was 16.0μA/cm². In addition, the fill factor FF was 0.63, and the photoelectric conversion efficiency was 5.02%. In addition, the fill factor FF is obtained by the maximum output (0.013×0.35)/open-circuit voltage (0.45)/short-circuit current density (0.016). In addition, the photoelectric conversion efficiency is obtained by the open-circuit voltage (0.45)×short-circuit current density (0.016)×fill factor FF (0.63)/irradiance (0.089)/100. Furthermore, a series resistance Rs of the element was 44.7 Ω·cm², and a parallel resistance Rsh was 3.28×10⁵ Ω·cm². In addition, the series resistance Rs and the parallel resistance Rsh were each obtained by measurement.

In addition, according to the I-V graph of FIG. 8A, in the photoelectric conversion element 100 of Example 1, a current density of 14 μA/cm² could be maintained at a bias voltage of 0.3 V.

In this example, the open-circuit voltage Voc is a voltage at a current density of zero. The short-circuit current density Jsc is a current density at a bias voltage of zero. The fill factor FF is a ratio of the maximum output to the product of the open-circuit voltage Voc and the short-circuit current density Jsc in the I-V graph. Hence, the photoelectric conversion efficiency is obtained by the open-circuit voltage Voc×short-circuit current density Jsc×fill factor FF/irradiance of incident light.

FIG. 8B is the I-V graph of the photoelectric conversion element 200 of Example 2. According to the graph in FIG. 8B, in the photoelectric conversion element 200 of Example 2, the open voltage Voc was 0.407 V, and the short-circuit current density Jsc was 17.0 μA/cm². In addition, the fill factor FF was 0.61, and the photoelectric conversion efficiency was 4.79%. Furthermore, the series resistance Rs of the element was 19.1 Ω·cm², and the parallel resistance Rsh was 3.49×10⁵ Ω·cm².

In addition, according to the I-V graph of FIG. 8B, in the photoelectric conversion element 200 of Example 2, a current density of 14 μA/cm² could be maintained at a bias voltage of 0.3 V.

FIG. 8C is the I-V graph of the photoelectric conversion element of Comparative Example. According to the graph in FIG. 8C, in the photoelectric conversion element of Comparative Example, the open-circuit voltage Voc was 0.391 V, and the short-circuit current density Jsc was 18.2 μA/cm². In addition, the fill factor FF was 0.41, and the photoelectric conversion efficiency was 3.27%. Furthermore, the series resistance Rs of the element was 670 Ω·cm², and the parallel resistance Rsh was 4.51×10⁴ Ω·cm².

In addition, according to the I-V graph of FIG. 8C, in the photoelectric conversion element of Comparative Example, the current density at a bias voltage of 0.3 V was remarkably decreased to 10 μA/cm² as compared to that of Example 1 or 2.

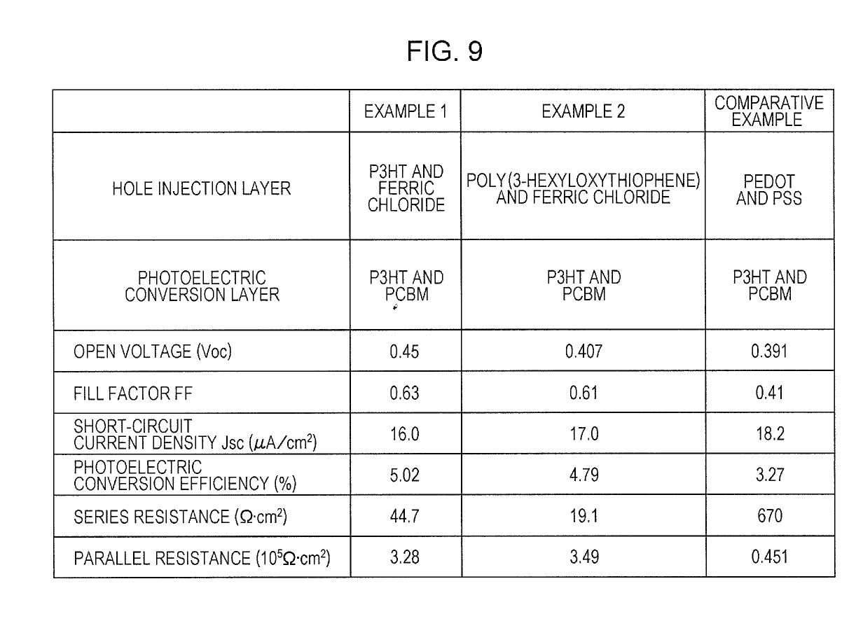

FIG. 9 is a table listing the features and electrical properties of the photoelectric conversion elements of Examples 1 and 2 and Comparative Example.

The series resistance Rs of the photoelectric conversion element 100 of Example 1 was decreased to 1/15 of that of the photoelectric conversion element of Comparative Example. The parallel resistance Rsh of the photoelectric conversion element 100 of Example 1 was improved by approximately seven times that of the photoelectric conversion element of Comparative Example. The open voltage-circuit Voc of the photoelectric conversion element 100 of Example 1 was improved by approximately 1.15 times that of the photoelectric conversion element of Comparative Example. The fill factor FF of the photoelectric conversion element 100 of Example 1 was improved by approximately 1.54 times that of the photoelectric conversion element of Comparative Example. The conversion efficiency of the photoelectric conversion element 100 of Example 1 was improved by approximately 1.54 times that of the photoelectric conversion element of Comparative Example.

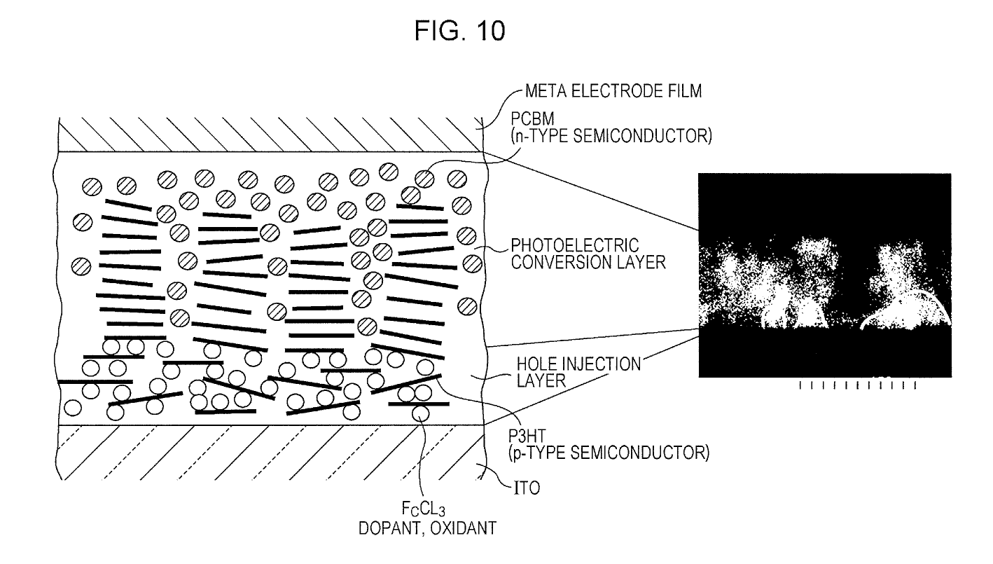

FIG. 10 is a schematic cross-sectional view of the photoelectric conversion element 100 of Example 1 and a cross-sectional photo of the photoelectric conversion element 100 corresponding to the above cross-sectional view.

In the cross-sectional photo, it is believed that a bright area indicates a low-density poly(3-hexylthiophene) (P3HT) 60. In this photo, the bright area has a pillar shape projecting from the hole injection layer 30. Hence, it is construed that in the photoelectric conversion layer 20 of Example 1, the poly(3-hexylthiophene) (P3HT) 60 is aggregated in a pillar-shaped region projecting from the hole injection layer 30. That is, it is construed that the poly(3-hexylthiophene) (P3HT) 60 is aggregated at the interface between the hole injection layer 30 and the photoelectric conversion layer 20. As a result, the contact between the PCBM 50 in the photoelectric conversion layer 20 and the poly(3-hexylthiophene) (P3HT) 60 in the hole injection layer 30 is suppressed. Accordingly, the leak current at the interface between the hole injection layer 30 and the photoelectric conversion layer 20 is reduced.

A photoelectric conversion element which has a high open-circuit voltage Voc or fill factor FF in a low light quantity region and which includes a photoelectric conversion layer formed from an organic thin film can be provided.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A method for manufacturing a photoelectric conversion element comprising:
forming a hole injection layer by applying a solvent containing a first p-type organic semiconductor and an oxidant capable of oxidizing the first p-type organic semiconductor on a transparent substrate and a transparent electrode provided on the transparent substrate and by removing the solvent by drying to oxidize the first p-type organic semiconductor with the oxidant;
forming a photoelectric conversion layer by applying a solvent containing an n-type organic semiconductor and a second p-type organic semiconductor on the hole injection layer and by removing the solvent by drying; and
forming a metal electrode using a metal layer on the photoelectric conversion layer.

2. The method for manufacturing a photoelectric conversion element according to claim 1, wherein the first p-type organic semiconductor has the identical main chain to that of the second p-type organic semiconductor.

3. The method for manufacturing a photoelectric conversion element according to claim 2, wherein the first p-type organic semiconductor and the second p-type organic semiconductor each include a polythiophene having a side chain at the 3-position of each thiophene unit.

4. The method for manufacturing a photoelectric conversion element according to claim 1,
wherein the oxidant is one of ferrous chloride, ferric chloride, fluorine, chlorine, bromine, and iodine.

5. A photoelectric conversion element comprising:
a transparent substrate;
a transparent electrode provided on the transparent substrate;
a hole injection layer which is provided on the transparent substrate and the transparent electrode and which contains a first p-type organic semiconductor oxidized by an oxidant:
a photoelectric conversion layer provided on the hole injection layer and containing an n-type organic semiconductor and a second p-type organic semiconductor having the identical main chain to that of the first p-type organic semiconductor; and
a metal electrode provided on the photoelectric conversion layer and containing a metal.
